(19) United States
(12) Patent Application Publication
(10) Pub. No.: US 2025/0291110 A1
(43) Pub. Date: Sep. 18, 2025

(54) LIGHT RECEIVING ELEMENT AND METHOD OF MANUFACTURING LIGHT RECEIVING ELEMENT

(71) Applicant: SUMITOMO ELECTRIC INDUSTRIES, LTD., Osaka (JP)

(72) Inventors: Takuya OKIMOTO, Osaka-shi (JP); Takuya MITARAI, Osaka-shi (JP)

(73) Assignee: SUMITOMO ELECTRIC INDUSTRIES, LTD., Osaka (JP)

(21) Appl. No.: 19/054,148

(22) Filed: Feb. 14, 2025

(30) Foreign Application Priority Data
Mar. 13, 2024 (JP) 2024-039325

(51) Int. Cl. G02B 6/122; H10F 30/223; H10F 71/00; H10F 77/124; H10F 77/40

(52) U.S. Cl. CPC G02B 6/1228; H10F 30/223; H10F 71/1272; H10F 77/1248; H10F 77/413

(57) ABSTRACT

A light receiving element includes a substrate including a silicon layer and a photodiode formed of a III-V group compound semiconductor and bonded to the silicon layer. The silicon layer includes a waveguide, the photodiode includes a first semiconductor layer, a light absorbing layer, and a second semiconductor layer, the first semiconductor layer is in contact with the silicon layer, the light absorbing layer and the second semiconductor layer are stacked in this order on a surface of the first semiconductor layer opposite to a surface of the first semiconductor layer in contact with the silicon layer, the first semiconductor layer has a first conductivity type, the second semiconductor layer has a second conductivity type, the first semiconductor layer includes a projecting portion and a first slab portion, and the projecting portion is connected to the first slab portion and projects from the first slab portion.

### CROSS REFERENCE TO RELATED APPLICATIONS

This application claims priority based on Japanese Patent Application No. 2024-039325 filed on Mar. 13, 2024, and the entire contents of the Japanese patent application are incorporated herein by reference.

### TECHNICAL FIELD

The present disclosure relates to a light receiving element and a method of manufacturing a light receiving element.

### BACKGROUND

A hybrid light receiving element can be formed by bonding a photodiode formed of a III-V group compound semiconductor to a substrate such as a silicon on insulator (SOI) substrate (silicon photonics) in which a waveguide is formed (for example, Non-patent literature 1: Ye Wang, et al. “High-Power Photodiodes With 65 GHz Bandwidth Heterogeneously Integrated Onto Silicon-on-Insulator Nano-Waveguides” IEEE Journal of Selected Topics in Quantum Electronics, Vol. 24, No. 2, 6000206, March/April 2018). The photodiode absorbs light propagated through the waveguide and outputs electric signal.

### SUMMARY

A light receiving element according to the present disclosure includes a substrate including a silicon layer; and a photodiode formed of a III-V group compound semiconductor and bonded to the silicon layer. The silicon layer includes a waveguide, the photodiode includes a first semiconductor layer, a light absorbing layer, and a second semiconductor layer, the first semiconductor layer is in contact with the silicon layer, the light absorbing layer and the second semiconductor layer are stacked in this order on a surface of the first semiconductor layer opposite to a surface of the first semiconductor layer in contact with the silicon layer, the first semiconductor layer has a first conductivity type, the second semiconductor layer has a second conductivity type, the first semiconductor layer includes a projecting portion and a first slab portion, and the projecting portion is connected to the first slab portion and configured to project from the first slab portion so as to overlap the waveguide.

### BRIEF DESCRIPTION OF THE DRAWINGS

FIG. 1A is a top view illustrating a light receiving element according to a first embodiment.

FIG. 1B is a perspective view illustrating a light receiving element.

FIG. 1C is an enlarged view of a projecting portion.

FIG. 2A is a cross-sectional view illustrating a light receiving element.

FIG. 2B is a cross-sectional view illustrating a light receiving element.

FIG. 3 is a diagram illustrating the loss of light.

FIG. 4A is a plan view illustrating a method of manufacturing a light receiving element.

FIG. 4B is a plan view illustrating a method of manufacturing a light receiving element.

FIG. 4C is a plan view illustrating a method of manufacturing a light receiving element.

FIG. 5A is a plan view illustrating a projecting portion of a light receiving element according to a first modification.

FIG. 5B is a plan view illustrating a projecting portion of a light receiving element according to a second modification.

FIG. 5C is a plan view illustrating a projecting portion of a light receiving element according to a third modification.

FIG. 5D is a plan view illustrating a projecting portion of a light receiving element according to a fourth modification.

FIG. 6A is a perspective view illustrating a light receiving element according to a second embodiment.

FIG. 6B is a diagram illustrating the loss of light.

FIG. 7 is a perspective view illustrating a light receiving element according to a third embodiment.

### DETAILED DESCRIPTION

The loss of light occurs between the waveguide of the substrate and the bonded photodiode. By reducing the loss of light, light receiving sensitivity can be increased. Thus, the object of the present disclosure is to provide a light receiving element and a method of manufacturing a light receiving element that can reduce the loss of light.

### Description of Embodiments of Present Disclosure

First, the contents of embodiments of the present disclosure will be listed and explained.

(1) A light receiving element according to one aspect of the present disclosure includes a substrate including a silicon layer; and a photodiode formed of a III-V group compound semiconductor and bonded to the silicon layer. The silicon layer includes a waveguide, the photodiode includes a first semiconductor layer, a light absorbing layer, and a second semiconductor layer, the first semiconductor layer is in contact with the silicon layer, the light absorbing layer and the second semiconductor layer are stacked in this order on a surface of the first semiconductor layer opposite to a surface of the first semiconductor layer in contact with the silicon layer, the first semiconductor layer has a first conductivity type, the second semiconductor layer has a second conductivity type, the first semiconductor layer includes a projecting portion and a first slab portion, and the projecting portion is connected to the first slab portion and projected from the first slab portion so as to overlap the waveguide. Since the photodiode includes the projecting portion, light is less likely to be reflected and scattered at an interface between the waveguide and the photodiode. The loss of light can be reduced.

(2) In the above (1), the projecting portion may include a first tapered portion, and the first tapered portion may have a shape tapering along a direction in which the waveguide extends. Light gradually transitions from the waveguide to the photodiode. The loss of light can be effectively reduced.

(3) In the above (1) or (2), the projecting portion may have a length of 2 μm or more. The loss of light can be reduced.

(4) In any one of the above (1) to (3), a distal end of the projecting portion may have a curved shape. Since light is not easily reflected, the loss of light can be reduced.

(5) In any one of the above (1) to (4), the photodiode may have a mesa, the mesa may include the light absorbing layer and the second semiconductor layer, may be disposed on a top of the first slab portion, and may face the projecting portion in the direction in which the waveguide extends. Light propagates through the waveguide, transitions to the photodiode in the projecting portion, and is absorbed by the light absorbing layer of the mesa. The photodiode can detect light.

(6) In the above (5), the mesa may include a second tapered portion, the second tapered portion may have a shape tapering along the direction in which the waveguide extends. The loss of light can be reduced.

(7) In the above (6), the second tapered portion may have a length of 5 μm or more. The loss of light can be reduced.

(8) In the above (5), the silicon layer may include a recessed portion and a second slab portion, the recessed portion may be a portion recessed from the second slab portion and may be disposed on each of two sides of the waveguide, the waveguide may be connected to an end portion of the second slab portion, and the first slab portion of the photodiode may be bonded to the second slab portion. Light is absorbed by the photodiode on the second slab portion. Light can be detected.

(9) In the above (8), the second slab portion may be configured to protrude more outward than the first slab portion, the waveguide may be configured to protrude more outward than the projecting portion. Even when a liquid such as an etchant enters the recessed portion, the lower surface of the photodiode is less likely to be contacted with the liquid. Etching from the lower surface can be prevented.

(10) A method of manufacturing a light receiving element includes bonding a photodiode formed of a III-V group compound semiconductor to a silicon layer of a substrate, and forming a slab portion and a projecting portion in the photodiode. The silicon layer includes a waveguide, the photodiode includes a first semiconductor layer, a light absorbing layer, and a second semiconductor layer, the first semiconductor layer is in contact with the silicon layer, the light absorbing layer and the second semiconductor layer are stacked in this order on a surface of the first semiconductor layer opposite to a surface of the first semiconductor layer in contact with the silicon layer, the first semiconductor layer has a first conductivity type, the second semiconductor layer has a second conductivity type, the first semiconductor layer includes the projecting portion and the slab portion, and the projecting portion is connected to the slab portion and configured to project from the slab portion so as to overlap the waveguide. Since the photodiode includes the projecting portion, light is less likely to be reflected and scattered at the interface between the waveguide and the photodiode. The loss of light can be reduced.

### Details of Embodiments of Present Disclosure

Specific examples of a light receiving element and a method of manufacturing a light receiving element according to embodiments of the present disclosure will be described below with reference to the drawings. The present disclosure is not limited to these illustrations, but is indicated by the scope of the claims, and is intended to include all modifications within the scope and meaning equivalent to the scope of the claims.

### First Embodiment

### (Light Receiving Element)

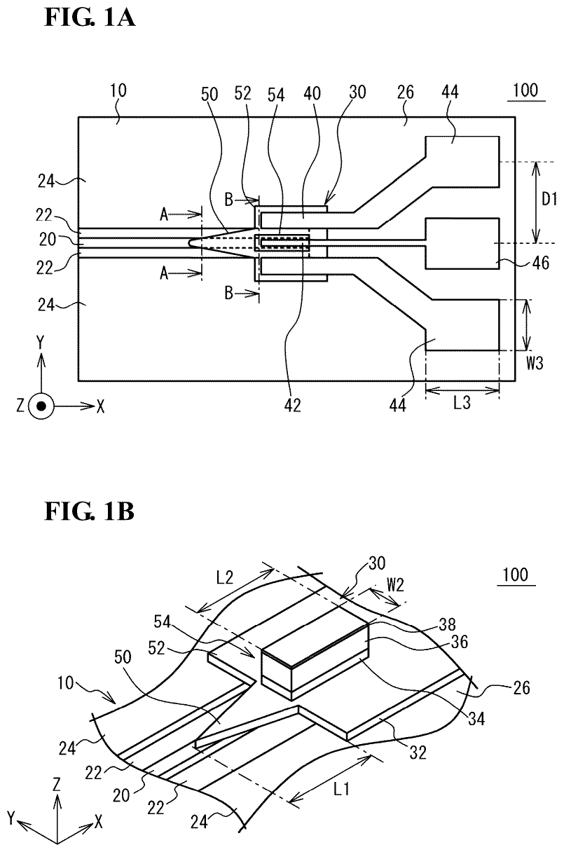

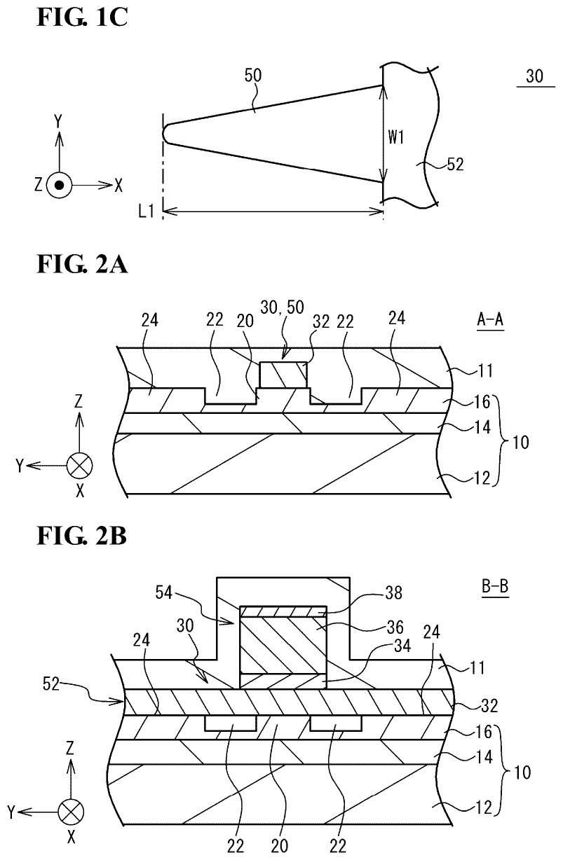

FIG. 1A is a top view illustrating a light receiving element 100 according to a first embodiment. FIG. 1B is a perspective view illustrating light receiving element 100. FIG. 1C is an enlarged view of a projecting portion 50. In FIG. 1A to FIG. 1C, an insulating film is omitted. In FIG. 1B electrodes are omitted. FIG. 2A and FIG. 2B are cross-sectional views each illustrating light receiving element 100. FIG. 2A illustrates a cross-section taken along line A-A of FIG. 1A. FIG. 2B illustrates a cross-section taken along line B-B of FIG. 1A.

As illustrated in FIG. 1A and FIG. 1B, light receiving element 100 is a hybrid light receiving element, and includes a substrate 10 and a photodiode 30. Photodiode 30 is bonded to a top surface of substrate 10. A Z-axis direction is a normal direction of the top surface of substrate 10. An X-axis direction is a direction parallel to the waveguide. A Y-axis direction is orthogonal to the X-axis direction and the Z-axis direction.

Substrate 10 includes a waveguide 20, a recessed portion 22, a terrace 24, and a slab portion 26 (second slab portion). Waveguide 20 and recessed portion 22 are parallel to the X-axis direction. In the Y-axis direction, recessed portion 22 is provided on each of two sides of waveguide 20. Outside recessed portion 22, terrace 24 is provided.

In FIG. 1A, waveguide 20, recessed portion 22, and terrace 24 are provided on the left side. Slab portion 26 is provided on the right side. Terrace 24 and slab portion 26 are planar. In the X-axis direction, waveguide 20 and recessed portion 22 extend from one end portion of substrate 10 to a position overlapping photodiode 30. Waveguide 20 is connected to one end portion of slab portion 26. In the Y-axis direction, slab portion 26 has a width larger than that of waveguide 20, and is connected to waveguide 20 and terrace 24.

As illustrated in FIG. 2A and FIG. 2B, substrate 10 is a silicon on insulator (SOI) substrate, and includes a substrate 12, a box layer 14, and a silicon (Si) layer 16 stacked in order in the Z-axis direction. Substrate 12 is formed of, for example, Si. Box layer 14 is formed of, for example, silicon oxide (SiO₂). A thickness of box layer 14 is, for example, 3 μm. A thickness of silicon layer 16 is, for example, 220 nm. The top surface of substrate 10 and a surface of photodiode 30 are covered with an insulating film 11. Insulating film 11 is formed of, for example, SiO₂ with a thickness of 1 μm. A refractive index of silicon layer 16 is 3.45. A refractive index of each of box layer 14 and insulating film 11 is 1.45, which is lower than that of silicon layer 16. These refractive indices are values for light having a wavelength of 1.55 μm. Waveguide 20, recessed portion 22, terrace 24, and slab portion 26 are provided in silicon layer 16 of substrate 10.

Waveguide 20, terrace 24, and slab portion 26 project in the Z-axis direction (upward direction) from recessed portion 22. The surfaces of waveguide 20, terrace 24 and slab portion 26 are located at the same height as each other. Recessed portion 22 is recessed from the surfaces of waveguide 20, terrace 24 and slab portion 26. Silicon layer 16 forms the bottom surface of recessed portion 22. The thickness of silicon layer 16 in recessed portion 22 is, for example, 30 nm. Recessed portion 22 may extend to the middle of silicon layer 16 in the Z-axis direction, or may extend to box layer 14 through silicon layer 16. Insulating film 11 is embedded in recessed portion 22.

Photodiode 30 is a semiconductor element formed of a III-V group compound semiconductor. Photodiode 30 is bonded to terrace 24 and slab portion 26 of silicon layer 16. As illustrated in FIG. 1B and FIG. 2B, photodiode 30 includes a semiconductor layer 32 (first semiconductor layer), a light absorbing layer 34, a semiconductor layer 36 (second semiconductor layer), and a contact layer 38. Semiconductor layer 32 is directly in contact with silicon layer 16 of substrate 10. Semiconductor layer 32 may be directly in contact with silicon layer 16 of substrate 10. Light absorbing layer 34, semiconductor layer 36, and contact layer 38 are stacked in this order on a surface of semiconductor layer 32 opposite to the surface of semiconductor layer 32 being in contact with substrate 10.

Semiconductor layer 32 is formed of, for example, indium phosphide (n-InP) of an n-type (first conductivity type). Semiconductor layer 32 is doped with, for example, silicon (Si). Light absorbing layer 34 is formed of, for example, undoped indium gallium arsenide (InGaAs). Semiconductor layer 36 is formed of, for example, indium phosphide (p-InP) of a p-type (second conductivity type). Contact layer 38 is formed of, for example, p+ type indium gallium arsenide ((p+)-InGaAs). Semiconductor layer 36 and contact layer 38 are doped with, for example, zinc (Zn). The semiconductor layers of photodiode 30 may be formed of a III-V group compound semiconductor other than the above.

As illustrated in FIG. 1A and FIG. 1B, photodiode 30 includes projecting portion 50, a slab portion 52 (first slab portion), and a mesa 54. As illustrated in FIG. 1B, projecting portion 50 and slab portion 52 include semiconductor layer 32. Mesa 54 includes light absorbing layer 34, semiconductor layer 36, and contact layer 38. As illustrated in FIG. 2A, projecting portion 50 is covered with insulating film 11. As illustrated in FIG. 2B, slab portion 52 and mesa 54 are also covered with insulating film 11.

As illustrated in FIG. 1A and FIG. 1B, slab portion 52 is provided in a range wider than mesa 54 and is bonded to terrace 24 and slab portion 26 of silicon layer 16. A width of slab portion 52 is larger than a width of projecting portion 50. Projecting portion 50 is connected to one end portion of slab portion 52 and projects from the end portion so as to overlap waveguide 20. The entire projecting portion 50 is a tapered portion (first tapered portion) and has a shape tapering along the X-axis direction. The width of projecting portion 50 is larger as it is closer to slab portion 52, and is smaller as it is farther from slab portion 52. A width W1 of a portion of projecting portion 50 connected to slab portion 52 illustrated in FIG. 1C is, for example, 2 μm. A length L1 of projecting portion 50 in the X-axis direction is, for example, 2 μm to 100 μm. A distal end of projecting portion 50 has a curved shape. Projecting portion 50 is line symmetric with respect to the X-axis direction.

Mesa 54 is disposed on a top of slab portion 52 and faces projecting portion 50 in the X-axis direction. A shape of mesa 54 is a rectangular parallelepiped. A length L2 of mesa 54 illustrated in FIG. 1B is, for example, 5 μm to 50 μm, and in one example, 30 μm. A width W2 of mesa 54 is, for example, 0.5 μm to 6 μm, and in one example, 2 μm. Waveguide 20 extends to an end portion of mesa 54 opposite to projecting portion 50. The n-type semiconductor layer 32, light absorbing layer 34, and the p-type semiconductor layer 36 form a PIN junction.

As illustrated in FIG. 1A, light receiving element 100 includes electrodes 40 and an electrode 42, a pad 44 and a pad 46. The electrodes and the pads are formed of metal. Two electrodes 40 are cathodes and are electrically connected to semiconductor layer 32. Pad 44 is electrically connected to electrode 40. Electrode 42 is an anode and is electrically connected to contact layer 38. Pad 46 is electrically connected to electrode 42.

A length L3 of pad 46 in the X-axis direction is, for example, 50 μm to 150 μm. A width W3 of pad 46 in the Y-axis direction is, for example, 50 μm to 100 μm. The size of pad 44 is, for example, the same as that of pad 46. A center-to-center distance D1 between pad 44 and pad 46 is, for example, 100 μm to 200 μm.

Light receiving element 100 detects light propagating through waveguide 20. The wavelength of the light to be detected is, for example, 1.55 μm, and may be 1.26 μm to 1.63 μm. A reverse bias voltage is applied to photodiode 30 using pads 44 and pad 46. Substrate 10 and photodiode 30 are optically coupled by evanescent optical coupling. Light propagates through waveguide 20 and transitions from waveguide 20 to photodiode 30. Light absorbing layer 34 of photodiode 30 absorbs light and generates photocarriers (hole-electron pairs). The photocarriers are output as photocurrent.

Photodiode 30 includes projecting portion 50 having a tapered shape. Light transitions from waveguide 20 to photodiode 30 in projecting portion 50. Since projecting portion 50 is provided, reflection and scattering of light between waveguide 20 and photodiode 30 are less likely to occur, and the loss of light is reduced. Since photodiode 30 absorbs high-power light, light receiving sensitivity is improved.

The mode of light propagating through waveguide 20 is a single mode. In projecting portion 50, a higher order mode may be generated. Photodiode 30 can absorb light in a single mode and a higher order mode and output electric signal.

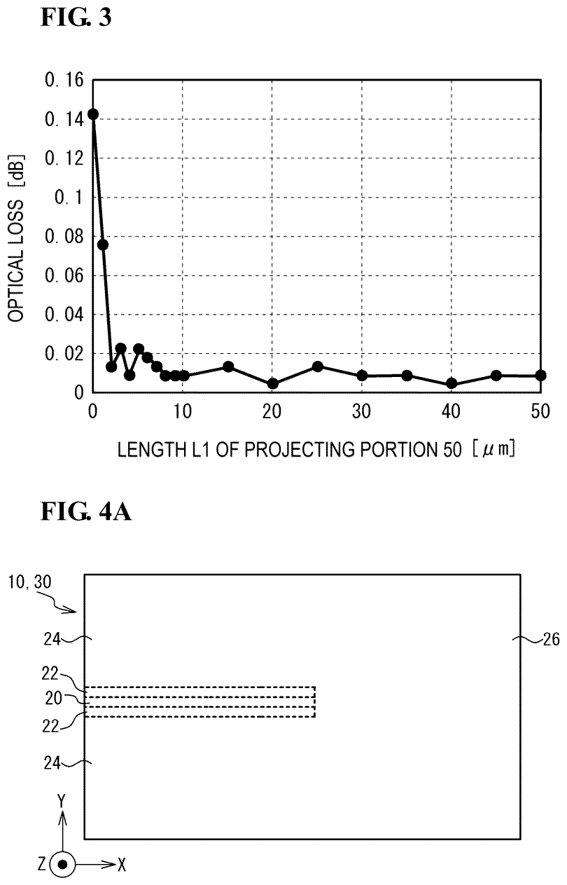

FIG. 3 is a diagram illustrating the loss of light. The horizontal axis represents the length L1 of projecting portion 50. The zero on the horizontal axis of FIG. 3 is an example where photodiode 30 does not include projecting portion 50. When the length L1 is larger than zero, photodiode 30 includes projecting portion 50. The vertical axis represents the calculation result of the loss of light at the interface between waveguide 20 and photodiode 30. The wavelength of light used for the calculation of the loss is 1.55 μm in vacuum. The approximate wavelength of light propagating through silicon layer 16 is the wavelength in vacuum divided by the refractive index of silicon layer 16. Projecting portion 50 has a tapered shape. The width W1 of projecting portion 50 is set to 2 μm.

When the length L1 is zero, the optical loss is 0.14 dB. Photodiode 30 includes projecting portion 50, and thus the optical loss is reduced. When the length L1 of projecting portion 50 is 2 μm or more, the optical loss is reduced to about 0.02 dB. When the length L1 of projecting portion 50 is longer than four times the wavelength of the light in projecting portion 50, the optical loss is 0.02 dB or less, which is small. When the length L1 is in a range of 6 μm to 50 μm, the optical loss is 0.02 dB or less.

### (Method of Manufacturing)

For example, dry etching is performed on silicon layer 16 of substrate 10. A portion exposed from a mask (not illustrated) is etched to form recessed portion 22. The portion covered by the mask (not illustrated) is not etched. Waveguide 20, terrace 24, and slab portion 26 are formed.

Contact layer 38, semiconductor layer 36, light absorbing layer 34, and semiconductor layer 32 are epitaxially grown in this order on an InP substrate different from the SOI substrate (substrate 10) by a metal organic chemical vapor deposition (MOCVD) method or the like. The InP substrate is diced to form photodiode 30. Photodiode 30 immediately after the dicing is a rectangular parallelepiped, and does not include projecting portion 50 or mesa 54.

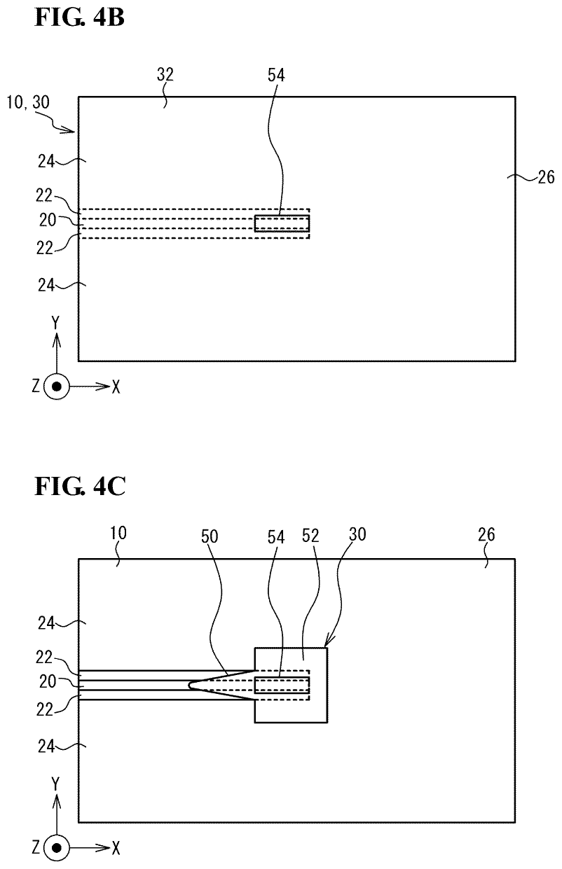

FIG. 4A to FIG. 4C are plan views each illustrating a method of manufacturing light receiving element 100. As illustrated in FIG. 4A, photodiode 30 is bonded to the top surface of substrate 10. In the bonding, one surface of silicon layer 16 and a surface of semiconductor layer 32 of photodiode 30 are irradiated with plasma to activate these surfaces. The surface of semiconductor layer 32 is contacted with the surface of silicon layer 16, and photodiode 30 is bonded to silicon layer 16. Photodiode 30 covers, for example, the entire top surface of silicon layer 16 and is disposed on or above waveguide 20, recessed portion 22, terrace 24, and slab portion 26. After the bonding, wet etching is performed to remove the InP substrate of photodiode 30. Semiconductor layer 32 to contact layer 38 remain.

As illustrated in FIG. 4B, mesa 54 is formed on photodiode 30. Portions of contact layer 38, semiconductor layer 36, and light absorbing layer 34 exposed from the mask (not illustrated) are removed by dry etching. Mesa 54 is formed in the portion covered by the mask. In the dry etching, for example, a chlorine-based etching gas is used. After the dry etching, the mask is removed. Semiconductor layer 32 of photodiode 30 covers the top surface of substrate 10.

As illustrated in FIG. 4C, slab portion 52 and projecting portion 50 are formed in photodiode 30. Mesa 54 and a part of semiconductor layer 32 are covered with a mask (not illustrated). A portion of semiconductor layer 32 exposed from the mask is removed by dry etching. Slab portion 52 and projecting portion 50 are formed by the dry etching. After the dry etching, the mask is removed.

By a vacuum deposition method and a lift-off method, electrodes 40 and electrode 42, pad 44 and pad 46 are provided. By cutting substrate 10, light receiving element 100 is formed.

According to the first embodiment, photodiode 30 is bonded to substrate 10. Semiconductor layer 32 of photodiode 30 includes projecting portion 50. Projecting portion 50 projects toward waveguide 20. Since photodiode 30 includes projecting portion 50, light is less likely to be reflected and scattered at the interface between waveguide 20 and photodiode 30. The loss of light can be reduced. Since photodiode 30 can absorb high-power light, light receiving sensitivity of light receiving element 100 is improved.

As illustrated in FIG. 1A to FIG. 1C, projecting portion 50 is a tapered portion. The refractive index continuously changes along the X-axis direction. Light gradually transitions from waveguide 20 to photodiode 30. The loss of light can be effectively reduced.

As illustrated in FIG. 3, by setting the length L1 of projecting portion 50 to be 2 μm or more, the optical loss can be greatly reduced. When the length L1 is in the range of 6 μm to 50 μm, the optical loss is 0.02 dB or less. In the example of FIG. 3, even when projecting portion 50 is lengthened to 20 μm or more, the optical loss is substantially the same. For example, the length L1 may be 2 μm to 20 μm. The length L1 may be 1.5 μm or more, 3 μm or more, 5 μm or more, or 10 μm or more, and 20 μm or less, or 30 μm or less.

As illustrated in FIG. 1C, the distal end of projecting portion 50 has a curved shape. The distal end has an arc shape or an elliptical arc shape in a plan view. The distal end of projecting portion 50 is not perpendicular to the light propagation direction. Light is not easily reflected by the distal end of projecting portion 50 and easily reaches photodiode 30. The loss of light can be reduced.

In waveguide 20, the mode of light is, for example, a single mode. Photodiode 30 can absorb both a single mode and a higher order mode. Thus, the higher order mode may be excited in projecting portion 50. The higher order mode spreads over a wider range in the cross section of photodiode 30 than the single mode. Light including a plurality of higher order modes is widely distributed from semiconductor layer 32 to semiconductor layer 36 in the cross section. The light intensity is not localized in light absorbing layer 34. Since the light intensity is not localized, the photocarriers are not localized. Photodiode 30 has high responsiveness not only to an optical signal having a low frequency but also to an optical signal having a high frequency. For example, light receiving element 100 can effectively perform a high-speed operation of 50 GHz or more.

Semiconductor layer 32 of photodiode 30 is in contact with silicon layer 16 of substrate 10. A layer of resin or the like is not provided between photodiode 30 and silicon layer 16. The loss of light can be reduced.

Photodiode 30 includes projecting portion 50, slab portion 52, and mesa 54. Projecting portion 50 overlaps waveguide 20. In a direction in which waveguide 20 extends, mesa 54 faces projecting portion 50. Light propagating through waveguide 20 transitions to photodiode 30 in projecting portion 50 and is absorbed by light absorbing layer 34 of mesa 54. Photodiode 30 can detect light.

Projecting portion 50 and slab portion 52 are formed of the n-type semiconductor layer 32. Mesa 54 includes light absorbing layer 34, the p-type semiconductor layer 36, and contact layer 38. A PIN junction is formed in photodiode 30. Light absorbing layer 34 absorbs light and generates photocarriers. The photocarriers are output. Light receiving element 100 can detect light.

Parasitic capacitance is generated in mesa 54. As mesa 54 increases in size, the parasitic capacitance increases. In a plan view, the area of mesa 54 is smaller than the area of slab portion 52. Since mesa 54 is small, the parasitic capacitance decreases. The influence on the operation of light receiving element 100 is reduced.

Semiconductor layer 32 is formed of, for example, n-InP. Semiconductor layer 36 is formed of, for example, p-InP. Light absorbing layer 34 is formed of, for example, InGaAs. Semiconductor layer 32, semiconductor layer 36, and light absorbing layer 34 may include a compound semiconductor other than the above. Semiconductor layer 32 may be of a p-type, and semiconductor layer 36 and contact layer 38 may be of an n-type.

Silicon layer 16 of substrate 10 includes waveguide 20, recessed portion 22, terrace 24, and slab portion 26. Waveguide 20 is connected to an end portion of slab portion 26. Slab portion 52 of photodiode 30 is bonded to slab portion 26. Light propagated through waveguide 20 is transferred to photodiode 30 and absorbed by photodiode 30 on slab portion 26. Light receiving element 100 can detect light.

### (First Modification and Second Modification)

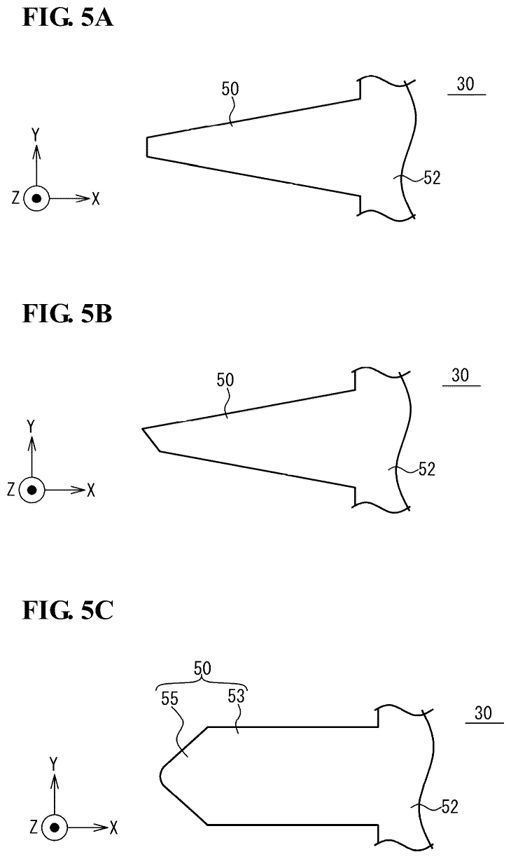

FIG. 5A is a plan view illustrating projecting portion 50 of a light receiving element according to a first modification. FIG. 5B is a plan view illustrating projecting portion 50 of a light receiving element according to a second modification. The description of the same configuration as that of the first embodiment will be omitted. As illustrated in FIG. 5A, in the first modification, the distal end of projecting portion 50 is a plane perpendicular to the X-axis. As illustrated in FIG. 5B, in the second modification, the distal end of projecting portion 50 is a slope, which is inclined with respect to the X-axis direction and the Y-axis direction. Projecting portion 50 is asymmetric with respect to the X-axis direction.

In the first modification and the second modification, photodiode 30 includes projecting portion 50, and thus, the loss of light can be reduced. As illustrated in FIG. 5A, when the surface of the distal end of projecting portion 50 is perpendicular to the light propagation direction (X-axis direction), light may be reflected by the surface. As illustrated in FIG. 5B, when the distal end of projecting portion 50 is inclined with respect to the X-axis direction, light is less likely to be reflected.

### (Third Modification and Fourth Modification)

FIG. 5C is a plan view illustrating projecting portion 50 of a light receiving element according to a third modification. FIG. 5D is a plan view illustrating projecting portion 50 of a light receiving element according to a fourth modification. The description of the same configuration as that of the first embodiment will be omitted. As illustrated in FIG. 5C, in the third modification, projecting portion 50 includes a portion 53 and a tapered portion 55. A planar shape of portion 53 is a straight line. Tapered portion 55 is located at the distal end of projecting portion 50 and has a tapered shape. As illustrated in FIG. 5D, in the fourth modification, the entire projecting portion 50 is linear.

In the third modification and the fourth modification, photodiode 30 includes projecting portion 50, and thus the loss of light can be reduced. As illustrated in FIG. 5D, when the entire projecting portion 50 is linear, the loss of light may occur. Further, since the surface of the distal end is perpendicular to the light propagation direction, reflection may increase. As illustrated in FIG. 5C, projecting portion 50 includes tapered portion 55, so that light gradually transitions from waveguide 20 to photodiode 30. The loss of light can be reduced. As illustrated in FIG. 1C, the entire projecting portion 50 may be a tapered portion. It is sufficient that at least a part of projecting portion 50 is a tapered portion.

### Second Embodiment

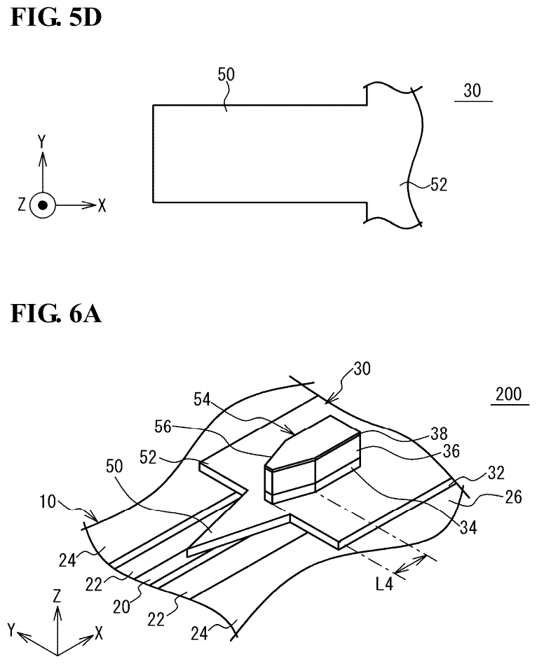

FIG. 6A is a perspective view illustrating a light receiving element 200 according to a second embodiment. The description of the same configuration as that of the first embodiment will be omitted. As illustrated in FIG. 6A, mesa 54 of photodiode 30 includes a tapered portion 56 (second tapered portion). Tapered portion 56 is disposed at a portion of mesa 54 close to waveguide 20 and is tapered along the direction in which waveguide 20 extends. In the X-axis direction, the portion of waveguide 20 located outside photodiode 30, projecting portion 50, and tapered portion 56 are arranged in order.

According to the second embodiment, semiconductor layer 32 includes projecting portion 50. Mesa 54 includes tapered portion 56. Photodiode 30 has a two-step taper structure, and thus, the optical coupling efficiency between waveguide 20 and light absorbing layer 34 can be increased. The loss of light can be reduced.

FIG. 6B is a diagram illustrating the loss of light. The horizontal axis represents the length L1 of projecting portion 50. The vertical axis represents the calculation result of the loss of light at the interface between waveguide 20 and photodiode 30. Projecting portion 50 has a tapered shape. The width W1 of projecting portion 50 is set to 2 μm. The length L1 of projecting portion 50 of semiconductor layer 32 and a length L4 of tapered portion 56 of mesa 54 in the X-axis direction are changed. The black circle and the solid line represent the example where the length L4 is zero. The dashed line and the square represent the example where the length L4 is 5 μm. The solid line and the diamond represent the example where the length L4 is 10 μm. The one dot chain line and the double circle represent the example where the length L4 is 15 μm. The dotted line and the triangle represent the example where the length L4 is 20 μm.

As illustrated in FIG. 6B, by setting the length L4 of tapered portion 56 to be, for example, 5 μm to 20 μm, the loss of light can be reduced as compared with the case where tapered portion 56 is not provided (L4=0). In case the lengths L1 of projecting portions 50 are the same, the optical loss is reduced as tapered portion 56 is longer. Regardless of the value of length L4, as long as the length L1 of projecting portion 50 was within a range of 7 μm to 50 μm, the optical loss was 0.02 dB or less. The length of mesa 54 in the X-axis direction is 30 μm. When the length L4 of tapered portion 56 is increased while the length of mesa 54 is kept constant, the areas of mesas 54 in plan view are reduced. The volume of light absorbing layer 34 is reduced. The light absorbing in photodiode 30 may be insufficient. The length L4 may be equal to or less than the length L2 of mesa 54 so that photodiode 30 can sufficiently absorb light.

### Third Embodiment

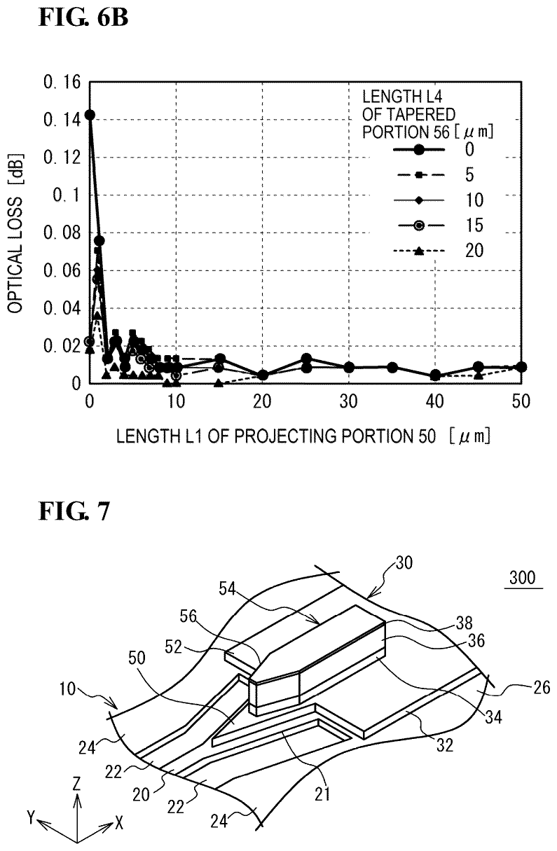

FIG. 7 is a perspective view illustrating a light receiving element 300 according to a third embodiment. The description of the same configuration as that of the first embodiment or the second embodiment will be omitted.

As illustrated in FIG. 7, slab portion 26 of substrate 10 is disposed in a range wider than slab portion 52 of photodiode 30, and protrudes more outward than slab portion 52 in the X-axis direction and the Y-axis direction. Waveguide 20 and recessed portion 22 extend to an end portion of slab portion 26 and do not extend to a position overlapping slab portion 52. In other words, slab portion 52 is not exposed to the air in recessed portion 22.

Waveguide 20 includes a tapered portion 21. A width of tapered portion 21 is larger as it is closer to slab portion 26 and is smaller as it is farther from slab portion 26. A portion of waveguide 20 other than tapered portion 21 has a constant width. Projecting portion 50 of photodiode 30 has a tapered shape and is bonded to tapered portion 21 of waveguide 20. The width of tapered portion 21 is larger than the width of projecting portion 50. Waveguide 20 protrudes more outward than projecting portion 50. The entire projecting portion 50 is disposed on a top of tapered portion 21 and is not exposed from the tapered portion to recessed portion 22.

Mesa 54 of photodiode 30 includes tapered portion 56. Tapered portion 56 is disposed on a top of projecting portion 50. A portion of mesa 54 that is not tapered is disposed on a top of slab portion 52.

According to the third embodiment, slab portion 52 of photodiode 30 is bonded to slab portion 26 of silicon layer 16. Slab portion 26 protrudes more outward than slab portion 52. Waveguide 20 protrudes more outward than projecting portion 50. The lower surface of photodiode 30 is not exposed from slab portion 26 to recessed portion 22. In other words, the entire lower surface of photodiode 30 is in contact with silicon layer 16. Even when a gas such as an etching gas used for dry etching and a liquid such as an etchant enter recessed portion 22, the gas and the liquid are less likely to be contacted with the lower surface of photodiode 30. Photodiode 30 is less likely to be etched from the lower surface, which can prevent delamination or the like.

Waveguide 20 includes tapered portion 21 corresponding to the tapered projecting portion 50. Since projecting portion 50 is bonded to tapered portion 21, projecting portion 50 less likely to be etched by the etchant in recessed portion 22. When the shape of projecting portion 50 is changed as illustrated in FIG. 5A to FIG. 5D, it is sufficient that waveguide 20 has a shape corresponding to projecting portion 50.

Each of waveguide 20, projecting portion 50, and mesa 54 includes a tapered portion. Since light receiving element 300 has a three-step taper structure, the loss of light can be reduced.

Mesa 54 may be a rectangular parallelepiped as in the first embodiment, and photodiode 30 may be bonded to slab portion 26 and may have a configuration without being exposed to recessed portion 22 as in the third embodiment.

Although the embodiments of the present disclosure have been described in detail, the present disclosure is not limited to the specific embodiments, and various modifications and changes can be made within the scope of the gist of the present disclosure described in the claims.

What is claimed is:

1. A light receiving element comprising:
a substrate including a silicon layer; and
a photodiode formed of a III-V group compound semiconductor and bonded to the silicon layer,
wherein the silicon layer includes a waveguide,
the photodiode includes a first semiconductor layer, a light absorbing layer, and a second semiconductor layer,
the first semiconductor layer is in contact with the silicon layer,
the light absorbing layer and the second semiconductor layer are stacked in this order on a surface of the first semiconductor layer opposite to a surface of the first semiconductor layer in contact with the silicon layer,
the first semiconductor layer has a first conductivity type,
the second semiconductor layer has a second conductivity type,
the first semiconductor layer includes a projecting portion and a first slab portion, and
the projecting portion is connected to the first slab portion and configured to project from the first slab portion so as to overlap the waveguide.

2. The light receiving element according to claim 1,
wherein the projecting portion includes a first tapered portion, and
the first tapered portion has a shape tapering along a direction in which the waveguide extends.

3. The light receiving element according to claim 1, wherein the projecting portion has a length of 2 μm or more.

4. The light receiving element according to claim 1, wherein a distal end of the projecting portion has a curved shape.

5. The light receiving element according to claim 1,
wherein the photodiode has a mesa,
the mesa includes the light absorbing layer and the second semiconductor layer, disposed on a top of the first slab portion, and faces the projecting portion in the direction in which the waveguide extends.

6. The light receiving element according to claim 5,
wherein the mesa includes a second tapered portion,
the second tapered portion has a shape tapering along the direction in which the waveguide extends.

7. The light receiving element according to claim 6, wherein the second tapered portion has a length of 5 μm or more.

8. The light receiving element according to claim 5,
wherein the silicon layer includes a recessed portion and a second slab portion,
the recessed portion is a portion recessed from the second slab portion and disposed on each of two sides of the waveguide,
the waveguide is connected to an end portion of the second slab portion, and
the first slab portion of the photodiode is bonded to the second slab portion.

9. The light receiving element according to claim 8,
wherein the second slab portion is configured to protrude more outward than the first slab portion,
the waveguide is configured to protrude more outward than the projecting portion.

10. A method of manufacturing a light receiving element, the method comprising:
bonding a photodiode formed of a III-V group compound semiconductor to a silicon layer of a substrate; and
forming a slab portion and a projecting portion in the photodiode,
wherein the silicon layer includes a waveguide,
the photodiode includes a first semiconductor layer, a light absorbing layer, and a second semiconductor layer,
the first semiconductor layer is in contact with the silicon layer,
the light absorbing layer and the second semiconductor layer are stacked in this order on a surface of the first semiconductor layer opposite to a surface of the first semiconductor layer in contact with the silicon layer,
the first semiconductor layer has a first conductivity type,
the second semiconductor layer has a second conductivity type,
the first semiconductor layer includes the projecting portion and the slab portion, and
the projecting portion is connected to the slab portion and configured to project from the slab portion so as to overlap the waveguide.
